(19) United States
(12) Patent Application Publication
(10) Pub. No.: US 2025/0253168 A1
(43) Pub. Date: Aug. 7, 2025

(54) Apparatus for Electrochemical Treating of a Semiconductor Substrate and a Process using the Apparatus

(71) Applicants: Infineon Technologies AG, Neubiberg (DE); RENA Technologies GmbH, Guetenbach (DE)

(72) Inventors: Iris Moder, Villach (AT); Bernhard Goller, Villach (AT); Petra Erika Fischer, Wernberg (AT); Norbert Bay, Freiburg (DE); Xavier Gay, Freiburg (DE)

(21) Appl. No.: 18/855,008

(22) PCT Filed: Apr. 12, 2023
(86) PCT No.: PCT/EP2023/059565

§ 371 Date: Oct. 8, 2024

(30) Foreign Application Priority Data
Apr. 14, 2022 (DE) 102022109284.4

(51) Int. Cl. H01L 21/67; H01L 21/3063

(52) U.S. Cl. CPC H01L 21/67086; H01L 21/3063

(57) ABSTRACT

An apparatus for electrochemical treating of a semiconductor substrate comprising at least one first tank filled with an electrolyte and comprising at least one first electrode, at least one second tank filled with an electrolyte and comprising at least one second electrode, and a separation unit that electrically separates the first and second tanks including their electrolytes, an electric power supply connected to the first and second electrodes, a transport means, which is configured for transporting the substrate over the first and second tanks, and a controller for controlling the transport means in a specific manner. Further, a process for electrochemical treating of a semiconductor substrate using the apparatus described herein is disclosed.

### TECHNICAL FIELD

The present disclosure generally relates to an apparatus for electrochemical treating of a semiconductor substrate and a process for electrochemical treating, for example porosifying, semiconductor substrates using the apparatus.

### BACKGROUND

Electrochemical etching processes commonly are used for preparing semiconductor substrates with different layer properties. Sometimes, the same processes are used for preparing porous layers having controlled porosities in surface areas of a semiconductor substrate. Generally, a porous layer is formed on a semiconductor substrate, such as a Si wafer, by anodic formation using the immersion of the substrate into hydrogen fluoride solution and applying a specific current density onto those regions of the substrate to be treated.

Such etching processes need the application of a current density in the region of treatment. For this, contacts at the backside of the substrate have been used in common processes. Some contacts are full contacts over the area of the back side of the substrate. Sometimes, ring contacts at the edge of the substrate wafers have been used. Alternatively, line contacts at the substrate surface or a substrate holder have been prepared, for example, as additional lithographic planes within or at the backside of the semiconductor substrate. Those full contacts or holders used for contacting the backside of a semiconductor substrate, however, resulted in difficulties with automatic processes or exclusions at the edges of the substrates which were not accurately treated. The line contacts in additional planes of the substrate or within the holder resulted in additional preparation steps, and thus low throughputs in the whole manufacturing process.

In the solar panel or solar cell production usually square wafer substrates are treated. The substrates are processed by electrochemical etching processes. Most of the common apparatus can treat substrate wafers having a square form with sufficient homogeneity but leads to problems with substrates having a round shape. It has been found in several experiments that the results with substrates having a round shape lead to inhomogeneities in their porosity of the treated areas when using a common treating apparatus.

In the light of the above, there is a demand of improved treatment processing conditions and improved apparatus which allow the processing of semiconductor substrates with different shapes. Moreover, there is a demand for apparatus allowing a homogenic current density application for substrates with different shapes over the time.

### SUMMARY

According to an embodiment, an apparatus for electrochemical treating of a semiconductor substrate comprises at least one first tank filled with an electrolyte and respectively comprising at least one first electrode, at least one second tank filled with an electrolyte and respectively comprising at least one second electrode, and a separation unit that electrically separates the at least one first tank from the at least one second tank including their electrolytes. In the present description, first electrodes and second electrodes mean different types of electrodes having different potentials. Hence, if the first electrode is an anode, the second electrode is a cathode and vice versa. Furthermore, the apparatus may comprise an electric power supply connected to the at least one first electrode and the at least one second electrode. The electric power supply may be configured to deliver electric current to the electrodes, while the current density is adjusted in view of the desired electrochemical treatment.

The apparatus further may comprise a transport means configured for transporting the substrate over the first and second tanks such that a surface of the substrate to be treated is in direct contact with at least one of the electrolyte filled in the at least one first tank and the electrolyte filled in the at least one second tank, thereby conducting a charge transfer between the at least one first electrode and the substrate and between the substrate and the at least one second electrode and resulting in an electrochemical treatment of the substrate surface. The charge transfer process results in an electrochemical treatment of the substrate surface. Transporting the substrate over the tanks means in the context of the present description that the substrate can move or is moved over the tanks filled with the electrolyte and brought into contact with the electrolyte by a fluid bridge connection. Thus, the distance from the electrolyte solution surface to the substrate surface to be treated is low enough to come into contact with the electrolyte and build up the fluid bridge due to the surface tension of the electrolyte. To close the gap between the wet electrodes, that means the electrolyte, and the substrate surface, the electrolytes can flow over the upper edges of the tanks. A continuous flow can be generated by a circular pumping of the electrolyte into the first or second tanks, for example through inlets in the bottom of the tank. The electrolyte flowing over the edges of the tank can be collected in collecting tanks and pumped again into the first or second tanks by an electrolyte pumping means. The transporting means for transporting the substrates over the first or second tanks may be selected depending on the general constructions and may include, for example, rotating rolls between or above the tanks and holding or robotic arms adjusted to move the substrate over the tanks with the wet electrolytes in a prescribed manner.

Moreover, the apparatus may comprise a controller for controlling the transport means such that the substrate masks, in a top view, the at least one first electrode and/or the at least one second electrode during the transport of the substrate over the first and second tanks most of the time during the electrochemical treatment of the substrate surface. Most of the time means in this regard, that at any time of the electrochemical treating process the substrate masks at least one of the electrodes. In particular, the electrode having an anodic potential may be masked by the substrate during the electrochemical treating process or during most of the time of the treating process. The electrode having a cathodic potential does not necessarily be masked by the substrate but can be arranged similar or symmetrically in its tank as the electrode with the anodic potential. At some points of the process, for example at a point of changing the direction of the substrate by the controller, none of the electrodes may be masked by the substrate at the same time. According to the embodiment described herein, this status lasts as short as possible. Accordingly, at least one of the first and second electrodes, in particular the electrode with the anodic potential, is masked more than 90%, particularly, more than 95%, more particularly more than 98% of the time of the electrochemical treating process.

An embodiment of a process for electrochemical treating of semiconductor substrates may use the apparatus according to any of the embodiments and/or examples described herein. The process may comprise a step of transporting the substrate over the first and second tanks. The transport means is thus configured such that a surface of the substrate to be treated is in direct contact with at least one of the electrolytes filled in the first and second tanks. In direct contact means that a liquid bridge between the substrate surface to be treated and the wet electrode, that means the electrolyte, in one of the first or second tanks is generated by approaching the substrate surface close to the electrolyte surface. If such a liquid bridge is generated, a charge transfer between the first electrode and the substrate and between the substrate and the second electrode can be achieved, resulting in an electrochemical treatment of the substrate surface. In this process, the substrate is moved to the first tank with the first electrode to bring the substrate surface in contact with the therein filled electrolyte and, thereby, bring the substrate surface to a positive potential. In this case the first electrode is an anode. Then, the substrate is transported to the second tank with the second electrode. At this time, the substrate surface is brought into contact with the wet electrode of the second tank to generate the desired reaction, for example, porosifying of the substrate surface in contact with the wet electrode of the second tank, which may be a cathode. During the treatment, the substrate is simultaneously in contact with the first and second tank to provide the current flow, however, different parts of the substrate surface to be treated are alternatingly in contact with the first electrolyte and, subsequently, with the second electrolyte. Thereby, the substrate surface to be treated may be moved alternating between the first and second tank(s) with the proviso that the substrate masks, in a top view, the at least one first electrode and/or the at least one second electrode during the transport of the substrate over the first and second tanks most of the time during the electrochemical treatment of the substrate surface. In particular, the electrode with the anodic potential may be masked during the electrochemical treating process. Thus, the whole substrate surface may evenly be treated.

### BRIEF DESCRIPTION OF THE DRAWINGS

The elements of the drawings are not necessarily to scale relative to each other, instead emphasis being placed upon illustrating the principles of the invention. Like reference numerals designate corresponding similar parts. The features of the various illustrated examples can be combined unless they exclude each other. Examples are depicted in the drawings and are detailed in the description which follows.

FIG. 1 illustrates the top view of the treating area of an apparatus according to an exemplary embodiment of the present application.

FIG. 2 illustrates the top view of the treating area of an apparatus according to another exemplary embodiment of the present application.

FIG. 3 illustrates the top view of the treating area of an apparatus according to a further exemplary embodiment of the present application.

FIG. 4 illustrates the top view of the treating area of an apparatus according to an exemplary embodiment of the present application.

FIG. 5 illustrates the top view of the treating area of an apparatus according to another exemplary embodiment of the present application.

FIG. 6 illustrate a cross-sectional view of a half-cell of the exemplary embodiment shown in FIG. 5.

FIGS. 7A-D illustrate cross-sectional views of four different alternatives of a half-cell of exemplary embodiments of the present application.

### DETAILED DESCRIPTION

In the following detailed description, apparatus for electrochemical treating of a semiconductor substrate and processes for electrochemical treating of semiconductor substrates using the apparatus are described. The semiconductor substrate may comprise or consist of at least one of a semiconductor wafer or one or more epitaxial layers. The epitaxial layers may comprise epitaxial structures, which, for instance, be provided within or on a surface region of the epitaxial layers or the wafer. For example, the substrate may comprise only epitaxial layers and may be devoid of a wafer. For example, a wafer that has been used for epitaxial growth might have been removed in previous process steps. In another example, a wafer may at least partly be present in the substrate, for example at the backside of the semiconductor substrate, while one or more epitaxial layers are provided thereon at the front side of the semiconductor substrate. Then, the semiconductor substrate which shall be treated can be the wafer at the backside thereof. For example, the semiconductor devices can be manufactured from semiconductor substrates, such as Si, SiC, GaN or other III/V or II/VI semiconductor substrates, whose surface area shall be treated by electrochemical processes as described herein. It is preferred that the substrate surface to be treated does not include lithographic elements in the treatment area of the surface. Of course, the apparatus may be used with other substrates which are suitable for electrochemical treating processes even though they are not described herein explicitly.

In the context of this application, electrochemical treating of a semiconductor substrate may comprise etching or porosifying a surface of the substrate by means of applying an electrochemical potential to the substrate, thereby changing the structure of the treated surface area, for example, increasing the porosity of the substrate surface. Such electrochemical treating processes generally are known in the technical field and the present application is not limited to specific ones. More particularly, the electrochemical treating may comprise the change of the porosity of the substrate surface to be treated. Depending on the current density applied, the thickness of the substrate surface area or the volume of the pores can specifically be adjusted.

The apparatus is equipped with at least two types of tanks, namely one or more first tanks and one or more second tanks. Two or more tanks of each type can be placed in an alternating manner or in a specific pattern if they are at least electrically separated by a separation means that electrically separates the neighboring first and second tanks. In the following the embodiments and examples are described in more detail by identifying the first tank as an anodic tank, the first electrode as an anode, the second tank as a cathodic tank, and the second electrode as a cathode. Alternatively, the first tank may be the cathodic tank and the second tank the anodic tank, wherein the respective corresponding electrodes are comprised therein. The skilled person will be able to adjust the respective anode and cathode arrangement in the following description of preferred examples of the apparatus and method of using the apparatus even though the specific embodiment is shown for the first alternative only.

According to an embodiment, the apparatus may comprise a treating area comprising the at least one first tank and the at least one second tank, wherein in a top view, the treating area has a circular or oval or elliptic shape. In some examples, the treating area may have an oval or elliptical shape, while the at least one first electrode and/or the at least one second electrode may be located in a circular arrangement inside the treating area. For example, at least two or at least three or even more than three first electrodes may be arranged in the first half of the circular treating area, that means within the first tank, next to each other on a circular line extending in both halves of the treating area. At least two or at least three or even more than three the second electrodes may be arranged in the second half of the treating area within the second tank at the same circular line. This arrangement allows that a substrate with a circular shape may mask all first and second electrodes at the same time if the substrate shape has a diameter being greater than the outer diameter of the electrode arrangement described above. A symmetrical arrangement of the first and the second electrodes as described in the above exemplified embodiment with circular arrangement of two or more (e.g. at least three) electrodes in each tank is optional only and may advantageously be used in a reverse pulse process as described herein later. The cathodic electrode(s) may be arranged outside the area covered by the substrate if no reverse pulse method is used. In particular, the anodic electrode(s) may be arranged such that they are masked by the substrate most of the time during the electrochemical treatment process in order to provide a sufficient homogeneity of the treated surface area of the substrate. Rotating the substrate over the two halves of the treating area, that means parts at the surface of the substrate mask the first electrodes within the first tank and the second electrodes of the second tank in an alternating manner, allows the electrochemical treatment of the substrate surface in a homogenous manner. To increase the homogeneity, a movement of the rotating substrate in linear direction along the oval or elliptic shape of the treating area may be carried out in addition to the rotational movement. In this case, it is preferred that the first and second electrodes are masked by the substrate most of the time of the treating process. Thus, the electrode array including the first and second electrodes may be configured such that the diameter of the circularly arranged electrode array is smaller than the diameter of the substrate. For example, the diameter of the electrode array may be in the range of about 5 to 90% of the diameter of the substrate, in some examples, the diameter of the electrode array will be in the range of about 30 to 70% of the diameter of the substrate. If more electrodes are used, the diameter of each of the electrodes may be at least 5% of the diameter of the substrate, more particularly, within a range of about 5 to 20%, for example.

According to a particular embodiment, the anodic tank may be filled with an electrolyte and comprises an anode for charging the electrolyte accordingly so that it can be used as a wet electrode. Similarly, the cathodic tank may be filled with the same or a different electrolyte and comprises a cathode. Exemplified electrolytes for electrochemical treatments of semiconductor substrates are HF solutions, optionally comprising an organic surface-active agent or organic solvent component such as ethanol, oxalic acid or acetic acid. The electrolytes filled in the tanks can function as wet electrodes once being brought into contact with the substrate to be treated. An electric power supply is connected to the anode and the cathode for generating the current flow once the surface of the substrate to be treated is in direct contact with at least one of the electrolytes filled in the anodic and cathodic tanks, thereby conducting a charge transfer from the anode to the substrate and from the substrate to the cathode and resulting in an electrochemical treatment of the substrate surface. The wet electrodes provided by the electrolytes in the cathodic and anodic tanks may be brought into contact with the surface of the substrate by means of liquid bridges which are generated and maintained by the surface tension of the electrolyte. Therefore, the distance between the wet electrode surfaces and the substrate surface is adjusted such that the surface tension can hold the liquid bridge during the movement of the substrate over the wet electrodes. Suitable distances are known in the technical field and depend on the surface tension of the electrolyte solution on the substrate surface. The electrolyte solution is pumped into the anodic and cathodic tanks, preferably from the bottom of the tanks, continuously such that the electrolyte flows over the upper edges of the tank walls. Thereby, the surface of the electrolyte is continuously renewed in this system. Moreover, the thus obtained electrolyte surface is somewhat higher than the wall edges of the tanks to facilitate the generation of the fluid bridges with the substrate surface to be treated. Moreover, any gas bubbles which may be generated during the chemical reactions at the substrate surface will be transported to the edges of the tanks and will be eliminated by the flow of electrolyte over the tank wall edges. This allows a further improvement of the treatment results.

The first or second electrode arranged in the first or second tanks, that means the anode or the cathode, may have any electrode shape suitable for generating the wet electrode in the respective tanks. Exemplified electrodes may be surface electrodes, which may be arranged at the bottom of each of the tanks. Alternatively, two or more electrodes may be arranged in the respective tanks instead. In some examples they are arranged in different parts of the tanks in order to generate a homogeneous potential within the respective tank. Generally, the form and material of the electrode may be selected such that the current density of the wet electrode generated at the surface of the electrolyte in each tank is homogeneous.

In some embodiments, the apparatus may further comprise a treating area covering means. The one or more treating area covering means may reduce the active treating area in its top view. Exemplarily, the treating area covering means may be arranged at those parts of the treating area provided by the first and second tanks in which neither first nor second electrodes are present. In case of an elliptical or oval treating area, for example, the electrodes may be present in a circular arrangement in the middle of the treating area. The treating area covering means, thus, extends over the whole treating area except having a circular opening in the middle with an opening diameter of at least the outer diameter of the circular arrangement of the first and second electrodes. Thus, the electrodes in this example are not covered by the treating area covering means. The function of the treating area covering means is to reduce the active area of the wet electrodes. The active area of the treating area is thus focused on the parts of the wet electrodes in which the first and second electrodes are placed within the first and second tanks. Moreover, the treating area covering means reduces the surface area of the electrolyte which is open to the surroundings. As the electrolyte generally evaporates from time to time, especially, if warmed due to the electrochemical reaction during the treatment, the treating area covering means allows a reduction of the evaporation of the electrolyte due to reducing the interface between the electrolyte and the environment.

In case of two tanks, one first tank and one second tank, placed in two halves of a circular or oval or elliptical treating area and being separated by the separation means, the first and second electrodes are placed near the separation area in the middle of the treating area. Then, the substrate can be moved over the first and second electrodes by a rotating movement which may optionally be overlaid by a small lateral movement, preferably in a direction perpendicular to the separation means. The diameter of the opening of the treating area covering means is in this case similar to the size of the substrate. Exemplary opening diameters are between about 50 to 250 mm, particularly between 60 mm and 160 mm, for example 60 mm or 75 mm or 150 mm. For a substrate with a diameter of 200 mm, the diameter of the opening may at least 170 and at most 230 mm, more particularly, within a range of about 180 to 220 mm.

The treating area covering means as described before may be configured in the form of a perforated plate which is provided at the level of the electrolyte in the first and second tanks or somewhat lower than the electrolyte level. Thus, gaseous products generated during the treating process may be guided out of the electrolyte because of the perforations in the treating area covering means. In some examples, the perforated plate may be made of a material having a low electric conductivity, for example made of plastic or polymeric materials. This allows an electric shielding at the outer circumference of the treating area and an improved homogeneity of the porosity of the wafer surfaces after the treatment.

According to some embodiments, the controller is adjusted to switch off at least parts of the first and second electrodes from the at least one first and/or the at least one second electrodes. Generally, those electrodes which are not masked by the substrate during the electrochemical treatment are switched off as long as they are not masked by the substrate. After the substrate is moved over those electrodes during its movement, the electrodes are switched on again. The controller may calculate the way of the substrate or receive measurement values of the substrate and will timely switch off the electrode current from the electrodes which are no longer within the movement way of the substrate. It is possible that the controller receives feedback measurement values from time to time or continuously. Alternatively, the way of the substrate and its timing is calculated before and the values are stored in the controller for each substrate before the electrochemical treatment starts. In this calculation, the size, the movement way, the velocity of the substrate movement, and further parameters may be included.

Switching off the current of parts of the electrodes, in particular, of those electrodes not actually masked by the substrate, improves the result of the electrochemical treatment, for example increases the homogeneity of the obtained porosity in the area of the whole substrate surface in contact with the electrolyte. It is assumed that the current flowing from the electrodes into the wet electrodes and then to the substrate may be more evenly distributed over the substrate surface when all active electrodes are masked by the substrate. Increased currents at the edges of the surface at those parts of the wet electrode where an active but not masked electrode is present are assumed to be avoided by switching off those non-masked electrodes.

According to some embodiments, the apparatus may further comprise current baffles. Those current baffles may be provided at least at parts of the treating area comprising the at least one first electrode and the at least one second electrode. Current baffles in this context means that they are means for deflecting or guiding the movement of the current generated by the electrodes into the wet electrolyte for harmonizing the current density of the wet electrolyte in the respective tank. The current baffles may be perforated sheets or nets, for example, made from a plastic or polymeric material. Generally, the material has a low electric conductivity. The current baffles may be provided in the first tank and in the second tank or in one of the tanks only. It is suitable to provide the current baffles in an area in which the first or second electrodes are located. In some examples, the whole tank is provided with a netlike current baffle. In other embodiments, the current baffle extends from the side of the electrodes until the treating area covering means. In this case, the current baffle covers the opening of the tank which is not covered by the treating area covering means. In some examples, the current baffle is provided at the same height within the tank as the treating area covering means, that means nearly at the level of the electrolyte surface or somewhat lower, for example about a few mm lower than the electrolyte surface. In some examples, the current baffle may not be parallel to the electrolyte surface but will be arranged in an inclined angle within the tank. For example, the upper end will be provided at the tank side near the separation means and the lower end will be near the location of the area which is covered by the treating area covering means. Alternatively, the upper end will be near the edge of the treating area covering means and will be inclined into the direction of the tank side which is near the separation means. Generally, the current baffles are provided in a plane which is higher than the upper end of the electrode or electrodes. Optionally, the current baffles may be extended over the whole area of the first and/or the second tanks, that means also below a treating area covering means, if provided at the circumference of a tank.

To avoid any direct contact between the two wet electrodes or the electrolytes of the anodic and cathodic tanks, the separation means may be provided around each anodic or cathodic tank and avoids that the current flows directly from one wet electrode to the other wet electrode. This allows that the current flow is from one electrode to the substrate and from the substrate to the other electrode once the substrate has been moved from one tank to the other tank with opposite potential. Generally, the substrate is positively charged by means of contacting the substrate surface with the wet electrode of the anodic tank, then moved to the cathodic tank and brought into contact with the wet electrode of the cathodic tank. In this cathodic half-cell, the substrate is electrochemical treated, for example by increasing the porosity of the substrate surface. Usually, the reaction includes a chemical reaction which may comprise the generation of gases. The type of physical or chemical reaction occurring at the cathodic charge transfer reaction depends on the substrate to be treated, the electrolyte, and the current density and potential applied in this tank. The respective reactions are known in the art and can easily be carried out with the use of the apparatus as described herein.

Exemplified separation means can be fixed walls or separate tanks without any electrolyte. Sometimes, air or an inert gaseous component is filled in the tanks of the separation means to avoid an electric contact between the electrolyte in the first tank and the electrolyte in the second tank. Alternatively, an air knife may be used to separate the first and second tanks. Air knives work with a stream of air or inert gas which usually enters the separation means at its bottom surface and provides a stream of air or inert gas from the bottom to the open space between the first tank and the second tank, thus providing an improved separation of the electrolytes filled in the first and second tanks, respectively. In addition, the stream of air or inert gas reaches the bottom surface of the substrate when being moved over the treating area and allows the separation of the anodic wet electrolyte and the cathodic wet electrolyte wetting the substrate surface during the electrochemical treatment process at the respective location over the anodic tank or the cathodic tank, respectively. Thus, the air knife is responsible for a separation of the anodic and cathodic tanks and the respective wet electrolytes, thus avoiding a direct current from the anodic wet electrolyte to the cathodic wet electrolyte. Additionally, a lip protruding into the way of the substrate and whipping the bottom of the substrate may be provided instead or in addition to the air knife as separation means.

According to an embodiment, the first tank or the second tank or both the first tank and the second tank, in their top views, may have a spiral shape and the first and the second tanks may be configured such that the first and second tanks are at least partly intertwined with each other. The spiral shape of the first or the second tank may provide a treating area having a mere circular shape. Because of this circular arrangement of at least one of the tanks, the first and/or the second tank, a substrate surface to be treated can be moved over the treating area such that a similar current density over the time at each part of the substrate surface can be achieved, even though the substrate has a round shape. This may improve the current density application for substrates with different shapes over the time. Especially, the porosities of the surfaces of especially round substrates such as semiconductor wafers may show an improved homogeneity if they are treated in an apparatus with first and/or second tanks having a spiral shape, in their top views.

In some examples, at least one of the first tank or the second tank, in a top view, spirally extend from a center of the apparatus outwardly. When the tank has a shape spirally extending from the center of the apparatus outwardly, the tank and the separation unit surrounding this tank, divide the apparatus into two separate regions, wherein one of the two regions is the first tank area. The second region may automatically be the second tank area which may be the area not occupied by the first tank area. In this second tank area, the second tank may be located such that it fills in the remaining space or is arranged only in one or more parts of the remaining space between the first tank area.

The separation means may be provided between the first and second tanks which may be in spiral shape and separated by the separation unit. Thus, according to some examples, the first or second tank spirally extending from the center outwardly may be arranged such that, in a top view, the tanks divide the apparatus into two separate regions each having a spiral shape. The area of the two spiral tanks may be similar or nearly identical. In the case of spirally extending first and second tanks, this can be achieved if the width of the tanks is similar or nearly identical at each part of the spiral shape which has the same distance to the center of the two spirally arranged first and second tanks. The two spirals may then be intertwined over the full length.

According to a further example, an apparatus for electrochemical treating of a semiconductor substrate comprises at least one first tank filled with an electrolyte and respectively comprising a first electrode, at least one second tank filled with an electrolyte and respectively comprising an electrode, and a separation unit that electrically separates the first tanks from the at least one second tank including their electrolytes. At least one means in this context one, two, three or more first or second tanks. Some examples may have two or more first tanks. In some examples, one smaller first tank is provided within the second tank, for example at the edge of the second tank. Then, the first tank is located at one segment of the second tank. The size and the shape of the first and second tanks can vary depending on the substrate and its shape, for example. For round wafers, for example, a circular second tank may include a first tank in one segment of the second tank, in its top view. If the second tank is shaped as a quadrate the first tank may be placed in one quarter of the second tank, for example. Alternatively, the first tank may have a circular form, even if the second tank has a rectangular shape.

Further, the apparatus may comprise an electric power supply connected to the at least one first electrode and the at least one second electrode, and a treating area. Furthermore, the apparatus may comprise a transport means which is configured for transporting the substrate over the first and second tanks such that a surface of the substrate to be treated is in direct contact with at least one of the electrolytes filled in the at least one first tank or the electrolyte filled in the at least one second tank, thereby conducting a charge transfer between the first electrode and the substrate and between the substrate and the second electrode and resulting in an electrochemical treatment of the substrate surface. The substrate surface to be treated can be contacted with the wet electrodes, that means by the electrolytes, of the first and second tanks by means of a liquid bridge as described for the previous embodiment, for example.

According to some examples, the treating area of the apparatus, in a top view, may have a circular shape. In case two or more first tanks are comprised, the first tanks may be arranged in separate sectors of the treating area, wherein a second tank may be arranged between neighboring ones of the first tanks and may be separated from the first tanks by the separation unit.

In some examples, the second tank may be separated into two or more tanks depending on the shape and configuration of the three or more first tanks. This specific configuration of several first tanks arranged within the second tank or tanks may allow an improved homogeneity of the obtained porous substrate surface even though the substrate shape is different to a square shape, for example, if wafers with generally round shapes are treated.

In some examples, the apparatus may comprise at least three first tanks. The at least three tanks may be circularly arranged with an n-folded rotationally symmetry within the treating area wherein n is the number of first tanks comprised in the apparatus of this example.

In further examples, the first tank in a first sector may have a smaller size in its surface area compared to the first tank in a second sector and, optionally, the size of the surface area of the first tank in the third and further sectors may be bigger than the surface area of the first tank in the second sector. This means that the surface area which is the effective treating area of the wet electrode provided by the first tank may be different from the effective treating area of the second and further first tanks. This may allow the finding of a treating way of the substrate surface over the whole treating area such that a similar current density over the time at each part of the substrate surface can be achieved, even though the substrate has a shape different from a square. This may improve the homogeneity of the current density application for substrates with complex shapes such as round shapes over the time.

In yet further examples, the first tanks in each of the sectors of the treating area of the apparatus may have a triangle or sector shape and their side walls may have different extensions from the outer rim of the treating area. In an example, the tips of the tanks are aligned such that they are positioned on a line formed in a spiral shape extending from the center of the bottom plane of the apparatus. Thus, the current density effectively applied to the substrate surface may be increased in each of the respective sectors with first tanks differently depending on the surface area provided by the respective first tank in this sector of the treating area. By spirally changing the surface area of the first tanks and, thus, of each of the wet electrodes responsible for the charge transfer, moving the substrate in a rotational manner around its own axis and a translational movement at the same time may increase the homogeneity of the current density applied to each part of the substrate. Hence, the use of this apparatus may improve the homogeneity of the treated substrate surfaces, such as the porosity of the substrate surface of a semiconductor wafer having a roundish shape.

According to another embodiment, an apparatus for electrochemical treating of a semiconductor substrate comprises a plurality of first tanks filled with an electrolyte each comprising a first electrode, a second tank filled with an electrolyte and comprising a second electrode, and a separation unit that electrically separates the first plurality of first tanks from the second tank including their electrolytes. Furthermore, the apparatus of this embodiment comprises an electric power supply connected to the first electrodes and the second electrode, and a transport means. The transport means is configured for transporting the substrate over the plurality of first tanks and the second tank such that a surface of the substrate to be treated is in direct contact with the electrolyte filled in the first tank and the electrolyte filled in the second tank, thereby conducting a charge transfer between the first electrode and the substrate and between the substrate and the second electrode and resulting in an electrochemical treatment of the substrate surface. The transport means is adjusted such that it may provide a stable liquid bridge between the substrate surface to be treated and the wet electrodes in the first and second tanks as described above for the first embodiment.

The apparatus may be further provided with a plurality of first tanks arranged in the second tank, thereby providing a treating area for carrying out the surface treatment reactions. Each of the first tanks may be electrically separated from the second tank by means of the separation unit which is placed around each of the first tanks. A plurality in this context means at least three or more first tanks within the second tank. Depending on the size of the first tanks, which usually is selected depending on the size of the substrate to be treated, more than three first tanks, particularly more than five or six tanks, may be provided within one second tank. A higher number of first tanks may improve the results of the electrochemical treated substrates, for example the homogeneity of the porous layer of the substrate.

In some examples, the first tanks may have a circular shape. Circular shape does mean in this context a round or nearly round shape while it may be elongated in one direction. In yet further examples, the first tanks may be arranged in a dot pattern within the second tank. More particularly, the dot pattern may be a regular arrangement in which the distance between neighboring first tanks is similar or identical.

According to an embodiment, the anodic tank or the cathodic tank or both of the tanks have, in its top view, a spiral shape. Moreover, at least one of the first or second tanks spirally extend from the center of the apparatus outwardly such that the bottom plane of the treating area of the apparatus is divided into two separate regions, namely the anodic tank area and the cathodic tank area, while the two regions have a spiral shape. Alternative, the two tanks may have a spiral shape and are intertwined with each other. In addition, they may be separated by the separation unit which is aligned between the two spirally shaped tanks or anodic and cathodic areas. The spiral shape of the tanks and of the separation unit is, according to this description, seen from its top view and describes the surface area of the tanks in a top view. Hence, from the upper perspective, the whole treatment area may be divided into alternating rings of anodic and cathodic treatment areas separated by the separation unit when viewed from one side to the opposite side of the whole treatment area. In view of this specifically patterned treatment area, the substrate surface or more particularly different parts of the substrate surface may be moved over the anodic and cathodic tanks with the respective wet electrodes in an alternating manner, thereby being applied with a positive or negative potential, also called pre-charged (while the term “pre-charged” in the context of the application does mean the application of a positive or negative potential onto parts of the surface of the substrate which are in contact with the wet electrolyte, for example, applying a positive potential in case the electrolyte is in contact with the anodic tank), and treated (the term “treated” means in the context of the application that parts of the substrate surface are electrochemically altered, e.g. porosified) alternately several times during the movement from one side to the other side of the treating area. In some embodiments, the substrate is moved over the treating area in a circular form following the spiral form of the tanks while being rotated around the own axis at the same time.

For moving the substrate over the above-described specific treatment area of the apparatus, a transport means for transporting the substrate over the anodic and cathodic tanks may be provided such that the substrate can freely be moved in a predefined manner from one wet electrode to the next wet electrode. “Moving” means in this context that the transport means is configured to rotate the substrate around its axis and, optionally, to move the substrate in a lateral direction over the first and second tanks. A motion in lateral direction may in this context be a translational movement of the substrate in a plane parallel to the planes of the first and second tanks, i.e. the upper surface of the anodic and cathodic tanks. Particularly, the movement is carried out such that the surface to be treated is close enough to generate a liquid bridge between the respective wet electrodes and the substrate surface. Other movements such as a rotation of the substrate which are overlaid over a translational motion are explicitly enclosed in this definition. In addition, the motion in lateral direction may comprise an eccentric movement of the substrate in a parallel plane to the planes of the first and second tanks. At the same time of such an eccentric movement, the substrate may be rotational driven by the transporting means in a predefined manner.

In some examples of the apparatus of this or former embodiments, in a top view, the treating area of the first tank is similar to the treating area of the second tank, for example, the treating area which may be identical to the bottom area of the first tank has a percentage of 90 to 110% compared to the treating area of the second tank. In case the treating areas of the first and second tanks are nearly identical, it is possible to use either the first tank as an anode tank, the first electrode as an anode, the second tank as a cathode tank, and the second electrode as a cathode or, alternatively, the first tank as a cathode tank, the first electrode as a cathode, the second tank as an anode tank, and the second electrode as an anode. Therefore, the cathode and anode treating areas can be interchanged by each other with the proviso that the two areas are alternately arranged. This may also allow applying a pulsed direct current with alternating polarity in such an embodiment without changing the treating time and treating area of the respective wet electrodes.

In a further example the apparatus for electrochemical treating a semiconductor substrate comprises at least one anodic tank, for example three or four anodic tanks, filled with an electrolyte, each comprising an anode, at least one cathodic tank filled with an electrolyte and respectively comprising a cathode, a separation unit that separates the anodic tanks from cathodic tanks including their respective electrolytes, and an electric power supply connected to the anodes and cathodes. The apparatus further comprises a transport means for transporting the substrate over the anodic and cathodic tanks such that a surface of the substrate to be treated may be in direct contact with at least one of the electrolytes filled in the anodic tanks or the electrolyte filled in the cathodic tanks, thereby conducting a charge transfer from the anode to the substrate and from the substrate to the cathode and resulting in an electrochemical treatment of the substrate surface as described in the above-identified example.

According to this example, the apparatus has a treating area in a circular shape. Circular shape does mean that the treating area with the anodic and cathodic tanks, in its planar shape from the top view, has a mostly circular shape. In some examples, it can be extended in one direction, that means being more oval than exactly circular. A plurality of first tanks (e.g. anodic tanks), in particular two or more first tanks, are arranged in separate sectors of the treating area, wherein a second tank (e.g. cathodic tank) is arranged between neighboring ones of the first tanks and is separated from the first tanks by the separation unit. The cathodic tank may be configured as a single tank or as two or more separated tanks arranged such that an alternating arrangement of anodic and cathodic tanks is generated in the main treating area of the apparatus, if seen from the prescribed moving path of the substrate over the anodic and cathodic tanks in the treating area. The cathodic tank may be separated from the anodic tanks by the separation unit such that the charge current flow between the two wet electrodes in the anodic and cathodic tanks is blocked from directly being transferred from one electrode to the other electrode. Thus, the current flow occurs from the anodic wet electrode to the substrate and from the substrate to the cathodic wet electrode as explained in the other examples before.

In an example of the apparatus for electrochemical treating of a semiconductor substrate, the anodic tanks which are provided in separate sectors of the treating area, may be circularly arranged with an n-folded rotationally symmetry in the treating area. In this example, n is the number of anodic tanks comprised in the apparatus of this embodiment. If three or four anodic tanks are provided in the treating area, the treating area is divided into three or more separate sectors each being interrupted by a cathodic tank each between two of the neighboring anodic tanks. The cathodic tanks may be combined with each other to one cathodic tank surrounding each of the anodic tanks. Hence, this exemplified apparatus allows an alternating arrangement of the anodic and cathodic tanks in a high symmetry improving the treatment results.

In some examples of this embodiment, the anodic tank in a first sector may have a smaller size in its surface area compared to the anodic tank in a second sector and, optionally, the size of the surface area of the anodic tanks in the third and further sectors may be bigger than the surface area of the anodic tank in the second sector. Therefore, the surface of the respective anodic wet electrodes in each of the sectors may have a different size and may result in a different current density applied to the substrate surface when being moved over this anodic tank during the treating process. More particularly, the specific configuration of the anodic tanks and, thus, the anodic wet electrodes with a higher treating area in the circumferential parts of the treating area may increase the potential applied on the outer areas of the substrate surface of circular substrates, while the potential applied in the center of the substrate may be decreased compared to the current treating processes. Thereby, the treatment result, such as the porosity of the substrate surface treated, can be influenced by the different sectors such that each part of the substrate surface achieves nearly the same potential over the treatment time. This may improve the homogeneity of the treatment result. Hence, the apparatus is suitably adjusted for the treatment of circular substrates such as semiconductor wafers.

In some other examples, the anodic tanks in each of the sectors may have a triangle or sector shape and their side walls have different extensions from the outer rim of the treating area of the apparatus, while the tips of the tanks are aligned such that they are positioned on a line formed in a spiral shape extending from the center of the bottom plane of the apparatus. Accordingly, the surface area of the anodic wet electrodes arranged in this embodiment is higher at the circumferential part of the circular treating area and may extend into the center of the treating area only from one side. Thus, this specific arrangement also allows to adjust the potential applied to the substrate surface in a manner that each part of the substrate surface achieves nearly the same current density over the treatment time, especially, during the treatment of circular substrates.

In yet another example, the apparatus comprises a plurality of anodic tanks filled with an electrolyte each comprising an anode which are arranged in a cathodic tank filled with an electrolyte and comprising a cathode. The apparatus further comprises a separation unit that electrically separates the anodic tanks from the cathodic tank including their electrolytes, an electric power supply connected to the anodes and the cathodes, and a transport means. The transport means is configured for transporting the substrate over the plurality of anodic tanks and the cathodic tank such that a surface of the substrate to be treated may be in direct contact with the electrolyte filled in the anodic tank or the electrolyte filled in the cathodic tank, thereby conducting a charge transfer from the anode to the substrate and from the substrate to the cathode and resulting in an electrochemical treatment of the substrate surface. The transport means may be adjusted such that it may provide a stable liquid bridge between the substrate surface to be treated and the wet electrolytes in the anodic and cathodic tanks as described above for the other examples.

The plurality of anodic tanks is arranged in the cathodic tank, thereby providing a treating area for carrying out the surface treatment reactions such as a porosification. Each of the anodic tanks is electrically separated from the cathodic tank by means of the separation unit which is placed around each of the anodic tanks. A plurality means in this context at least three or more anodic tanks within the cathodic tank. A higher number of anodic tanks for pre-charging the substrate surface to be treated may improve the results of the obtained substrates, for example the homogeneity of the porous layer of the substrate.

According to the process for electrochemical treating of semiconductor substrates using the apparatus according to one of the previously described embodiments, the substrate may be transported or moved over the anodic and cathodic tanks in an alternating manner so that the parts of the substrate surface are pre-charged in the anodic treating area and surface treated in the cathodic treating area. The surface of the substrate to be treated may be in direct contact with at least one of the electrolytes filled in the anodic and cathodic tanks such that a liquid bridge between the substrate surface to be treated and the wet electrolyte in one of the anodic and cathodic tanks is generated by approaching the substrate surface close to the electrolyte surface. If such a liquid bridge is generated, a charge transfer between the respective electrode and the substrate can be achieved, resulting in an electrochemical treatment of the substrate surface. In this process, the substrate may be moved to the anodic tank with the anode to bring the substrate surface in contact with the therein filled electrolyte and, thereby, bring the substrate surface to a positive potential. Subsequently, the substrate is transported to the cathodic tank with the cathode. At this time, the substrate surface is brought into contact with the wet electrode of the cathode to generate the desired reaction, for example porosifying of the substrate surface in contact with the wet electrode of the cathodic tank, i.e. the cathode. During the treatment, the substrate or at least parts or the substrate are moved alternating between the anodic and cathodic tanks so that the whole substrate surface is evenly treated over the time. The treating time generally depends on the reaction carried out, the substrate material, the potential applied to the substrate surface, and the current density in the parts of the substrate to be treated. For semiconductor substrates such as wafers with 6 to 8 inches (150 to 200 mm) made of Si or SiC, the treating time may be adjusted within the range of several minutes, for example about 5 to 60 minutes, more particularly, 10 to 30 minutes, in particular about 15 to 20 minutes. The time for larger wafers may be longer.

A regular distribution of the first tanks within the second tank in the treatment plane and moving direction improves the result of the treatment. A higher regularity in the distribution may result in a higher homogeneity of the electrochemical treatment reaction.

The herein described process may, for example, be used for porosifying a semiconductor substrate such as a round wafer. In some examples, the process is defined by using a power supply which supplies direct current to the electrodes. For example, the direct current may be applied to the anode for pre-charging the semiconductor substrate in at least parts of its surface to be treated, that means a positive potential is applied to parts of the substrate surface which are in contact with the anodic electrolyte. During this process, electrochemical reactions may occur at the surface of the substrate treated by applying current density. Depending on the applied current density it is possible that gaseous components may be generated near the substrate surface. As the substrate surface at this treating area is fully wetted by the anodic wet electrode, it is possible that gas bubbles under the substrate will appear. By moving the substrate over the anodic and cathodic tanks, the gas bubbles may be transported to the rand of the wetted area. Once being at the rand of the wetted area, the gas bubbles will easily be strived up from the substrate surface. As explained above, the electrolyte is pumped into the tanks continuously such that the electrolyte flows over the edges of the tank walls. In this electrolyte flow, the gas bubbles get be carried with into an electrolyte overflow tank. As the gas bubbles avoid the pre-charging (applying a positive potential) of the surface beneath the bubbles, the treating reaction is lowered in the next step if they are not transported away from the substrate surface continuously. Hence, the substrate is regularly moved by either rotating the substrate and by a translational motion so that the number and the size of gas bubbles are reduced at the treating area.

As the treating reaction at the cathodic tank area also may cause gaseous products, the movement of the substrate over the cathodic treating area has the same effect as described with regard to the anodic treating area. Hence, it is preferred to avoid or limit the number of gas bubbles underneath the substrate surface to be treated as much as possible by rotating the substrate and moving the substrate over the treating area with a desired speed. The speed is adjusted such that the number and size of the gas bubbles is small.

In alternative embodiments, the direct current may be applied over a short time and then the polarity of the direct current applied is changed to the opposite. Hence, the process according to this example may comprise a power supply which supplies pulses of direct power alternately having a different polarity in each pulse. Exemplified pulse lengths are in the range of several seconds. In some examples, especially, if the anodic and the cathodic treating area have a similar or an identical area, the pulse lengths may be below 1 second, for example, 200 to 900 ms, more particularly, 300 to 600 ms, in particular about 400 ms.

Generally, the treating area of each of the anodic and cathodic tanks is adjusted such that it is high enough to apply sufficient current density at the substrate surface to be treated. The higher the treating area, the higher is the current which can be applied to the substrate by the wet electrodes. Hence, the treating time can be lowered, and the electrochemical reaction generated can be improved. Especially, the treating area of the cathodic tank is responsible for an improved surface treatment depending on the current density applied on the substrate surface.

Further embodiments will be described by referring to the drawings which show different types of arrangements of the first and second tanks, in their top view.

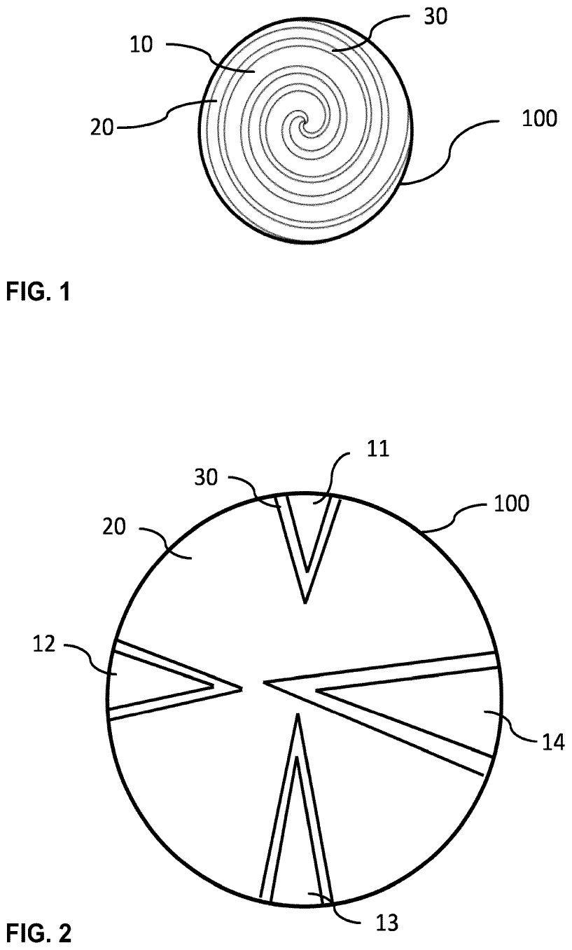

Referring now to FIG. 1 a schematic view of an apparatus for electrochemical treating a round wafer is shown. In particular, the treating area 100 of the apparatus is shown with its specific arrangement of an anodic tank 10 and a cathodic tank 20 and a separation means 30 between the two tanks. Not shown are the electric power means and the transport means. Furthermore, the anode and the cathode located inside the anodic tank and the cathodic tank, respectively, are not shown either. The electrodes may be one or more electrodes arranged in the tanks but may also be surface electrodes provided at the bottom of the tanks.

The treating area is preferably larger than the wafer to be treated. For 200 mm wafers, the diameter of the treating area 100 may be at least 250 mm. The dimension of the anodic tank 10 and the cathodic tank 20, including the side walls, but excluding the separation means 30 are about 25 to 50 mm, in this example shown in FIG. 1, about 35 mm. Thus, the anodic tank may be twisted several times, for example, about 2.5 times around the center of the treating area, if the diameter of the treating area is about 350 mm. If a larger treating area is used, the anodic tank may be twisted 3, 4 or even more times around the center.

The apparatus is equipped with an anodic tank 10 which, in a top view, spirally extend from the center of the treating area 100 and a cathodic tank 20 which also has a similar spirally shaped form, in its top view, wherein the cathodic tank is located in the spaces between the spirally shaped anodic tank. Thus, the treating area 100 may be divided in two similar treating areas, namely the anodic treating area and the cathodic treating area. Between both tanks, the separation means 30 is located and electrically separates the anodic tank and the cathodic tank. For electrically connecting the substrate surface to be treated, the electrolyte, generally an HF based electrolyte containing at least about 15% ethanol, for example 30-60% ethanol, more particularly about 50% ethanol, may be pumped from the bottom of the anodic and cathodic tanks into the respective tank. As the tanks have an open upper end, the electrolyte is flowing over the tank walls and is collected in a collecting tank (not shown). The separation means 30 may be a common separation means such as an air knife, for example, which is spirally formed between the anodic and cathodic tanks 10,20 over the full length of the anodic tank wall. Alternatively, a whipping means may be used instead of the air knife shown in this embodiment.

The substrate, herein the round wafer, is transported by means of the transport means in form of a holding arm over the treating area. As the treating area is larger than the wafer substrate, only those parts of the substrate surface are pre-charged which are in contact with the anodic wet electrode. The parts simultaneously being in contact with the cathodic wet electrode may be electrochemically treated because of the current flow through the substrate parts being not in contact with the first and second electrolytes. During the translational movement over the treating area, the part of the substrate surface which has been pre-charged before is moved to the cathodic tank and its treating area. At this position, the previously pre-charged substrate surface is in contact with the cathodic wet electrode, thereby causing the electrochemical treatment at the substrate surface. In this case, the semiconductor wafer surface is porosified depending on the current density applied. The next cycle at this part of the substrate surface is carried out as soon as the substrate is moved over the next part of the anodic tank.

In order to avoid direct electric flow between the anode and the cathode, the substrate surface is either whipped with a lip of the separation means directed on the substrate surface between the anodic and cathodic tanks or by the air stream provided by the air knife as shown in this embodiment. This circle of pre-charging and treatment steps are consecutively carried out during the movement of the substrate surface over the treating area 100. At the same time of the lateral movement over the treating area 100 in a linear translational movement or a swinging motion, the substrate can be rotated around its own axis to generate a more homogeneous treatment reaction, thereby achieving a homogeneous porosification of the whole substrate surface area.

In the treating area 100 shown in FIG. 1, the anodic tank 10 and the cathodic tank 20 have nearly the same surface area. Thus, it is possible to carry out a process in which the anodic and cathodic treating areas are changed by using direct current with pulses of alternating polarity. Then the anodic tank with the anode will be the cathodic tank with the cathode in the next pulse. Using this alternating direct current, it is possible to reduce the problems caused by gaseous products generated during the electrochemical treatment process. The gas bubbles may cause problems also known as diffusion problem at gas solid interphases. If the reaction is alternatingly changed from time to time, the generation of gas bubbles in the pores and at the surface of the substrate can be reduced. Thus, a higher electrochemical treatment can be achieved using the pulsed mode of direct current.

If one of the tanks has a significantly higher surface area, the use of pulsed direct current may not result in an improvement of the treatment results as the pre-charging and the treatment processes are related to the surface area of the respective treating area. If the anodic and cathodic treating area are too different from each other, the positive effect on the reducing of bubbles may be reduced while the effective treatment yield may be reduced at the same time. Hence, it is preferred to use anodic tanks 10 and cathodic tanks 20 with similar treating surface areas such as in the embodiment shown in FIG. 1.

Referring now to the embodiment shown in FIG. 2, the treating area 100 of the apparatus for electrochemical treating a semiconductor substrate comprises four anodic tanks (11; 12; 13; 14) filled with an electrolyte and each comprising an anode (not shown). The cathodic tank 20 is placed around each of the four anodic tanks and separated from the anodic tanks by separation means 30. The separation means 30 is arrange next to the walls of the anodic tanks and, thus, allows a total separation of the anodic and cathodic tanks 10,20. The power supply and the anodes and cathodes are not explicitly shown in FIG. 2.

The treating area 100 of the apparatus in this embodiment has at least a diameter of 250 mm if it is used for 200 mm wafer substrates. The separation means 30 has a width between the wall of the anodic tank and the wall of the neighboring cathodic tank of about 15 mm or more. The area of the anodic tanks may be increased by increasing the anodic tanks in each sector or by increasing the number of the anodic tanks arranged in the cathodic tank. In the example shown in FIG. 2, the anodic tank 11 has a smaller surface area than anodic tank 12, and anodic tank 12 has a smaller surface area than anodic tank 13, and this is even smaller than the surface area of anodic tank 14. Moreover, the anodic tank 14 extends at least to the center of the treating area, while the three other tanks do not extend into the center. The tips of the four anodic tanks, if combined, follow a spiral line within the treatment area, in the top view. The current density applied to the surface of the substrate at the center may, thus, be similar compared to the areas at the circumference of a round substrate. Therefore, by using this specific arrangement of anodic tanks, the usual increase of treating processes in the center of a round wafer as evaluated in the common processes can be avoided or at least lowered.

If two anodic tanks extend into the center of the treating area from two sides, it is possible to combine the separation means and to arrange two or more cathodic tanks between each of the neighboring anodic tanks. The surface area of the cathodic tanks may be increased to allow a shorter treatment time.

Like the previous embodiment, the wafer is moved over the treating area in this embodiment in an eccentric movement and is rotated around its own axis. Thereby, each part of the wafer surface to be treated receives similar or the same current density and is treated over the same time with the same result. Therefore, the porosity of the surface of the substrate is homogenous even though a round wafer substrate is treated.

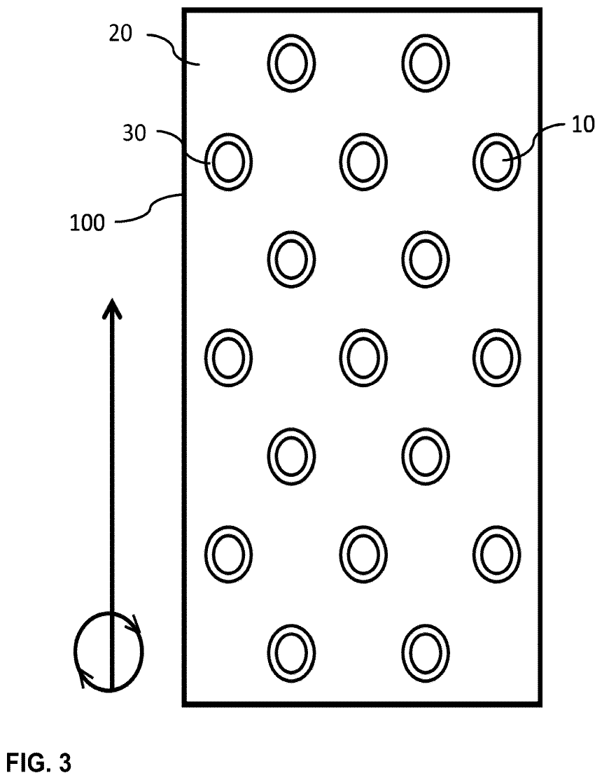

Referring now to FIG. 3, this embodiment of an apparatus as described herein has a treating area 100 which substantially is identical to the cathodic tank 20. The cathodic tank in this example is a rectangular tank with side walls in which the electrolyte is filled. The electrolyte is pumped from the bottom into the cathodic tank 20 and flows over the side walls during the treatment. Therefore, the apparatus comprises an electrolyte collecting tank which is placed below the cathodic tank 20 and anodic tanks 10. In the cathodic tank, a plurality of anodic tanks 10 are arranged in a regular dot-like pattern. Each anodic tank 10 is separated from the cathodic tank by a common separation means, for example a whipping tool as described with other examples herein, for electrically separating the cathodic and anodic tanks. The anodic tanks may also be filled with an electrolyte which continuously flows over the edge of the side walls of the anodic tanks 10 and are collected in a separate electrolyte collecting tank. From this tank, the electrolyte can again be pumped into the anodic tanks 10 so that a continuous renewing of the anodic treating surface, the wet electrode, may be guaranteed. In this example, the cathodic tank comprises a surface electrode as cathode. The anodes are common electrodes. Any other electrode form can be used as cathode and anode in this embodiment.

The substrate is moved over the elongated rectangular treating area 100 in a lateral motion which is superposed by a rotation of the substrate around its axis. This can be done by using a handling arm of the transport means which holds the substrate by means of a vacuum suction for example. As the anodes and electrodes are in the anodic tanks and cathodic tank, no electric connection of the substrate with the transporting means is needed and the holding arm can freely be moved, and the substrate can freely be rotated. An exemplified movement direction is given at the left side of the apparatus shown in FIG. 3.

Depending on the size and arrangement of the anodic tanks 10, the substrate surface can be pre-charged during the linear movement of the wafer over the treating area 100 at those parts being in contact of the anodic electrolyte, while simultaneously a porosification reaction takes place at parts of the substrate surface being in contact with the cathodic electrolyte. During the movement of the substrate over the anodic and cathodic tanks, the substrate may be treated at all parts of its surface in a homogeneous manner during the prescribed treatment time. The number and the pattern and size of the anodic tanks can be adjusted to the treatment process needed. Similar current densities may be applied in this embodiment as in the other embodiments.

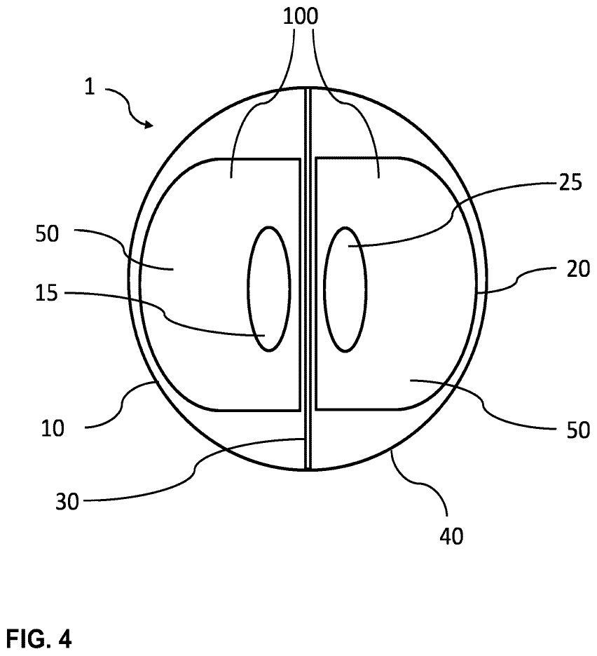

Referring now to FIG. 4, a schematic view of another embodiment of an apparatus 1 for electrochemical treating a substrate, e.g., a round wafer, is shown. In particular, the apparatus 1 is shown with its specific arrangement of an anodic tank 10, a cathodic tank 20, a separation means 30, a collection tank 40, electrodes 15,25, and a treating area 100. In top view, the surface area of the anodic tank 10 and the cathodic tank 20, respectively, may be shaped like a crescent. In this example, the two crescent-shaped tanks 10, 20 are placed next to each other at one side and generate an overall surface area in an elliptic or ellipsoidal shape. The total surface area of the two tanks 10, 20 is the treating area 100. The anodic tank 10 and the cathodic tank 20 are arranged next to each other at their linear side, respectively, and are separated with the separation means 30 placed between the two tanks 10, 20. In this example, the separation means is an air knife in which an air stream continuously flows from the bottom to the upper side of the separation means, thus, avoiding that the two wet electrolytes will be contacted with each other.

Around the anodic tank 10 and the cathodic tank 20 and the separation means 30, a collecting tank 40 is provided for receiving and collecting the wet electrolyte which flows over the tank walls of the anodic tank 10 and the cathodic tank 20. The collected wet electrolyte will be continuously pumped back to the anodic tank 10 and the cathodic tank 20 to keep them at a steady surface state for the electrochemical treatment. Not shown are the pumps for pumping the electrolyte, the electric power means and the transport means for transporting the substrate over the treating area 100 and bringing the surface thereof in contact with the wet electrolytes.

Furthermore, an anode 15 and a cathode 25 are located inside the anodic tank 10 and the cathodic tank 20, respectively. The electrodes 15, 25 may be arranged at apposition near the separation means 30 in the tanks 10 and 20, respectively, as shown in this example but may in other embodiments also be surface electrodes provided at the bottom of the tanks.

The treating area 100 is in this example larger than the wafer to be treated. For 200 mm wafers, the length of the treating area 100 may be at least 250 mm. In some examples, the length of the treating area at its shortest length may be between 250 and 500 mm, for example about 350 mm.

The apparatus equipped with the anodic tank 10 and the cathodic tank 20 has a total treating area 100 which is divided in two similar treating areas, namely the anodic treating area and the cathodic treating area. Between both tanks, the separation means 30 is located and electrically separates the anodic tank and the cathodic tank. For electrically connecting the substrate surface to be treated, the electrolyte, generally an HF based electrolyte containing at least about 15% ethanol, for example 30-60% ethanol, more particularly about 50% ethanol, may be pumped from the bottom of the anodic or cathodic tank into the respective tank. As the tanks have an open upper end and the electrolytes are continuously pumped into the tanks, the electrolyte is flowing over the tank walls and is collected in the collecting tank 40.

The substrate, e.g. a round wafer, is transported by means of the transport means (not shown) in form of a holding arm over the treating area. As the treating area 100 is larger than the wafer substrate, only parts of the substrate surface are pre-charged, i.e. applied with a positive potential, when being in contact with the anodic wet electrode. The parts of the substrate surface being in contact with the cathodic wet electrode will be treated because of the current flow. At these parts of the substrate surface, the electrochemical treatment at the substrate surface will be caused. During the translational movement over the treating area, the part of the substrate surface which has been pre-charged previously is moved to the cathodic tank and its treating area. At this position, these parts of the substrate surface now being in contact with the cathodic wet electrode are at the position to cause the electrochemical treatment at the substrate surface. In this case, the semiconductor wafer surface is porosified depending on the current density applied. The next cycle at this part of the substrate surface is carried out as soon as the substrate is moved over the next part of the anodic tank 10. In order to avoid direct electric flow between the anode 15 and the cathode 25, the substrate surface is, for example, whipped with a lip (not shown) of the separation means 30 directed on the substrate surface between the anodic and cathodic tanks or by means of the air stream directed upwards onto the substrate surface from the bottom of the separation means 30. In some embodiments, only a lip or an air knife system is used as separation means. This circle of pre-charging and treatment steps are consecutively carried out during the rotational and/or lateral movement of the substrate surface over the treating area 100. At the same time of the rotational movement of the substrate over the treating area 100, the substrate can be moved in a linear translational movement or a swinging motion to generate a more homogeneous treatment reaction.

In the treating area 100 shown in FIG. 1, the anodic tank 10 and the cathodic tank 20 have nearly the same surface area. Thus, it is possible to carry out a process in which the anodic and cathodic treating areas are changed by using direct current with pulses of alternating polarity. Then the anodic tank 10 with the anode 15 will be the cathodic tank 20 with the cathode 25 in the next pulse. Using this alternating direct current, it is possible to reduce the problems caused by gaseous products generated during the electrochemical treatment process. The gas bubbles may cause problems also known as diffusion problem at gas solid interphases. If the reaction is alternatingly changed from time to time, the generation of gas bubbles in the pores and at the surface of the substrate can be reduced. Thus, a higher electrochemical treatment can be achieved using the pulsed mode of direct current.

If one of the tanks has a significantly higher surface area, the use of pulsed direct current may not result in an improvement of the treatment results as the pre-charging and the treatment processes are related to the surface area of the respective treating area. If the anodic and cathodic treating area are too different from each other, the positive effect on the reducing of bubbles may be reduced while the effective treatment yield may be reduced at the same time. Hence, it is preferred to use anodic and cathodic tanks with similar treating surface areas such as in the embodiment shown in FIG. 4.

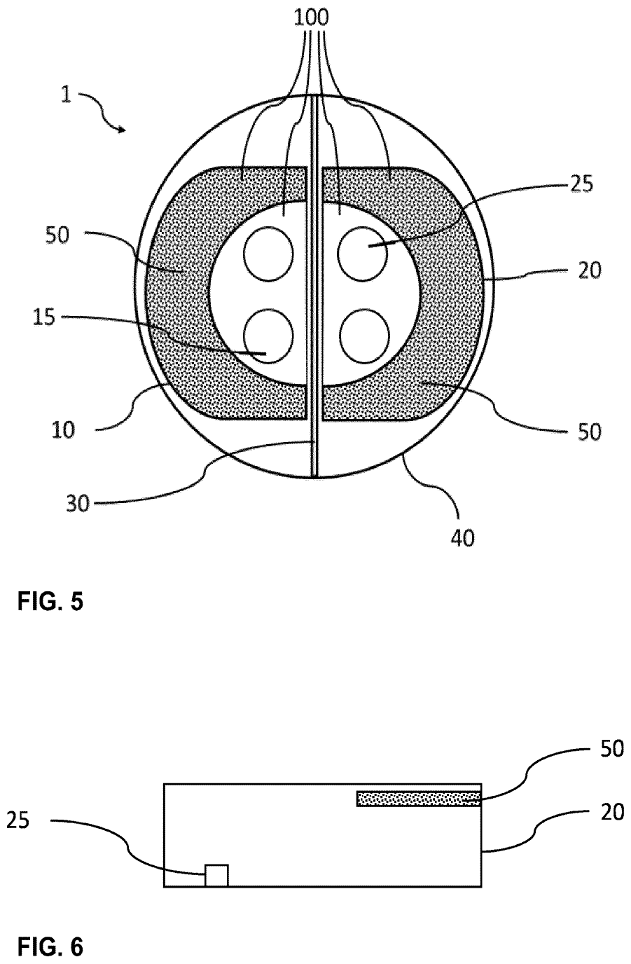

Referring now to FIG. 5, a schematic view of a further embodiment of an apparatus 1 for electrochemical treating a substrate, e.g. a round wafer, is shown. In particular, the apparatus 1 is shown with its specific arrangement of an anodic tank 10, a cathodic tank 20, a separation means 30, a collection tank 40, electrodes 15,25, and a treating area 100. All of these devices are similar or identical to those described in the embodiment shown in FIG. 4.

In this embodiment, however, each of the anodic tank 10 and the cathodic tank 20 comprises more than one electrode 15, 25. In some different embodiments, only one of the anodic tank 10 and the cathodic tank 20 may comprise more than one electrode 15, 25, while the other one of the anodic tank 10 and the cathodic tank 20 comprises exactly one electrode 15, 25. In the embodiment depicted in FIG. 5, four electrodes, in particular means two anodes 15 and two cathodes 25, are located inside the anodic tank 10 and the cathodic tank 20, respectively. In this example, two anodes 15 and two cathodes 25 are provided in the respective tanks in the middle of the treating area 100. In other embodiments, three anodes 15 and three cathodes 25, or even more than three anodes 15 and three cathodes 25, may be provided, in particular following a circular arrangement in the middle of the treating area 100. That is to say, the anodes 15 and the cathodes 25 together may follow a circle.

The electrodes 15, 25 may be arranged in an array in the tanks as shown in this example but may in other embodiments also be arranged non-symmetrically or as surface electrodes provided at the bottom of the tanks. The symmetrical arrangement of the anodes 15 and cathodes 25, especially near to the separator means allows the use of a reverse pulse application because then the respective electrodes advantageously are masked most of the time during the electrochemical treatment of the substrate surface.

The substrate, e.g. a round wafer, is transported by means of the transport means (not shown) in form of a holding arm over the treating area and the electrochemical treatment is carried out as described with regard to the embodiment shown in FIG. 5.

In this embodiment, parts of the anodic treating area of the anodic tank 10 and parts of the cathodic treating area of the cathodic tank 20 are covered at its surface with a treating area covering means 50. The treating area covering means may be provided at the outer circumference of the crescent-shaped anodic tank 10 and of the crescent-shaped cathodic tank 20. In the middle of the treating area 100, there is a circular hole in the two treating area covering means provided in the anodic tank 10 and the cathodic tank 20, respectively. Thus, the anodes 15 and cathodes 25 are not covered by the treating area covering means 50. The treating area covering means generally reduce the evaporation of the wet electrolytes during the treatment action. Furthermore, the treating area covering means may improve the guidance of gas bubbles generated during the electrochemical treatment process at the surface of the substrate to the outer circumference of the anodic tank 10 or the cathodic tank 20. At the same time the treating area covering means may shield the active treating area 100 and, thus, may improve the homogeneity of the current flow from the wet electrolyte to the substrate.

In the treating area 100 shown in FIG. 1, the anodic tank 10 and the cathodic tank 20 have nearly the same surface area. Thus, it is possible to carry out a process in which the anodic and cathodic treating areas are changed by using direct current with pulses of alternating polarity. Then the anodic tank 10 with the anode 15 will be the cathodic tank 20 with the cathode 25 in the next pulse. Using this alternating direct current, it is possible to reduce the problems caused by gaseous products generated during the electrochemical treatment process. The gas bubbles may cause problems also known as diffusion problem at gas solid interphases. If the reaction is alternatingly changed from time to time, the generation of gas bubbles in the pores and at the surface of the substrate can be reduced. Thus, a higher electrochemical treatment can be achieved using the pulsed mode of direct current.

If one of the tanks has a significantly higher surface area, the use of pulsed direct current may not result in an improvement of the treatment results as the pre-charging and the treatment processes are related to the surface area of the respective treating area. If the anodic and cathodic treating area are too different from each other, the positive effect on the reducing of bubbles may be reduced while the effective treatment yield may be reduced at the same time. Hence, it is preferred to use anodic and cathodic tanks with similar treating surface areas such as in the embodiment shown in FIG. 5.

Referring now to FIG. 6, a cross-sectional view of a half-cell of the exemplary embodiment shown in FIG. 5 is shown in greater detail. The cross-sectional view has been taken in the middle of the apparatus 1 and perpendicular to the separation means 30. In FIG. 6, the cathodic tank 20 is shown comprising the cathode 25 (only one of the electrodes comprised in this embodiment is shown in this cross-sectional view) and the treating area covering means 50.

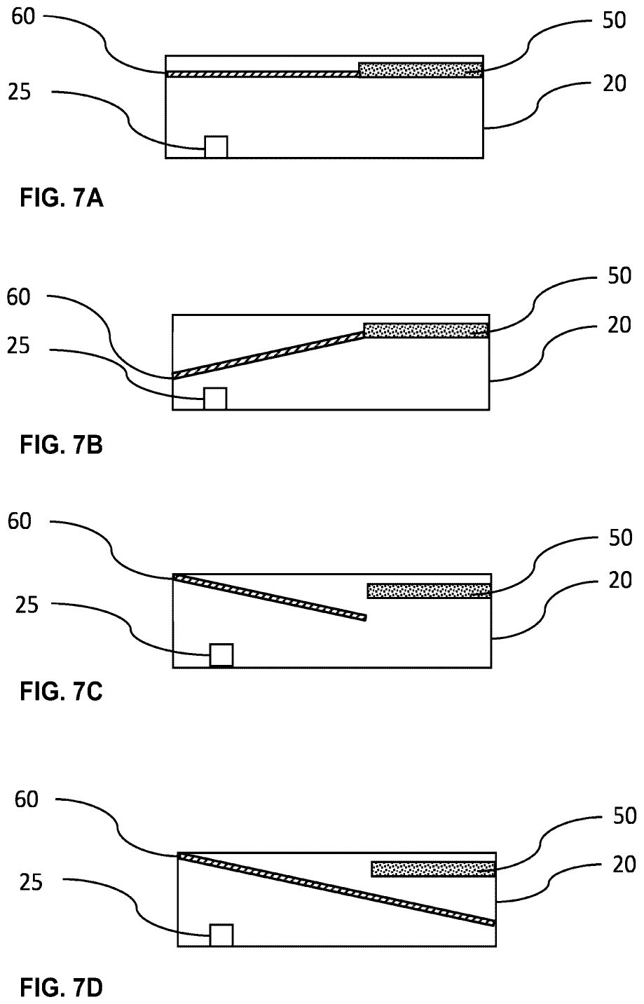

Referring now to FIG. 7, cross-sectional views of four different alternatives of a half-cell of exemplary embodiments of the application are shown. In any of the four alternatives, the same general configuration of the electrode 25 and the treating area covering means 50 as in the embodiment shown in FIG. 6 is shown. In addition, the cathodic tank in the embodiment shown in FIG. 7A comprises a horizontal current baffle 60 covering the open treating area not covered by the treating area covering means 50. The current baffle 60 is made of a net of a polymeric material having a low electric conductivity.

In the example shown in FIG. 7B, the cathodic tank 20 comprises a current baffle 60 which extends from the end of the treating area covering means 50 to the wall of the cathodic tank 20 near the side of the separation means (not shown). The current baffle 60 in this example is in an inclined position within the treating area while one end is mounted below the surface area of the wet electrolyte at the wall of the cathodic tank in a height of at most 50% of the height of the cathodic tank 20. The inclination angel may be adapted depending on the necessity of deflecting or guiding the movement of the current generated by the electrodes into the wet electrolyte for harmonizing the current density of the wet electrolyte in the respective tank.

In the examples shown in FIGS. 7C and 7D, the current baffle 60 is inclined in the other direction compared to the example shown in FIG. 7B and is mounted at the wall of the cathodic tank 20 close to the surface of the wet electrolyte. The current baffle then will go deeper under the electrolyte surface and will protrude into the cathodic tank 20. Its end may be at a position which is, in a top view, below the edge of the treating area covering means 50. In the example shown in FIG. 7D, the current baffle extends throughout the total cathodic tank 20. The current baffles may be mounted on mounting means extending from the bottom of the cathodic tank and may be screwed on these mounting means, for example.

Of course, the current baffles may be provided in the first tank and in the second tank. Thus, the examples shown in FIGS. 7A-7D for the cathodic tank may be implemented into the anodic tank in the same or similar manner at the same time.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

It is to be understood that the features of the various embodiments described herein may be combined with each other, unless specifically noted otherwise. Although specific embodiments have been illustrated and described herein, it will be appreciated by those of ordinary skill in the art that a variety of alternate and/or equivalent implementations may be substituted for the specific embodiments and examples shown and described without departing from the scope of the present disclosure. This application is intended to cover any adaptations or variations of the specific embodiments discussed herein. Therefore, it is intended that this disclosure be limited only by the claims and the equivalents thereof, while specific examples are the described in the following.

### EXAMPLE 1

Apparatus for electrochemical treating of a semiconductor substrate comprising:
a first tank filled with an electrolyte and comprising a first electrode,
a second tank filled with an electrolyte and comprising a second electrode,
a separation unit that electrically separates the first and second tanks including their electrolytes,
an electric power supply connected to the first electrode and the second electrode, and
a transport means;
   wherein the transport means is configured for transporting the substrate over the first and second tanks such that a surface of the substrate to be treated is in direct contact with the electrolyte filled in the first tank or the electrolyte filled in the second tank, thereby conducting a charge transfer between the first electrode and the substrate and between the substrate and the second electrode and resulting in an electrochemical treatment of the substrate surface,
   wherein, the first tank or the second tank or the first and the second tanks, in their top views, have a spiral shape and are configured such that the first and second tanks are at least partly intertwined with each other.

### EXAMPLE 2

Apparatus for electrochemical treating of a semiconductor substrate according to example 1, wherein, in a top view, at least one of the first tank or the second tank spirally extend from a center of the apparatus outwardly.

### EXAMPLE 3

Apparatus for electrochemical treating of a semiconductor substrate according to example 2, wherein the first or second tank spirally extending from the center outwardly divides, in a top view, the apparatus into two separate regions having a spiral shape.

### EXAMPLE 4

Apparatus for electrochemical treating of a semiconductor substrate comprising:
at least one first tank filled with an electrolyte and respectively comprising a first electrode,
at least one second tank filled with an electrolyte and respectively comprising a second electrode,
a separation unit that electrically separates the at least one first tank from the at least one second tank including their electrolytes,
an electric power supply connected to the at least one first electrode and the at least one second electrode,
a treating area comprising the at least one first tank and the at least one second tank, wherein, in a top view, the treating area has a circular shape, and
a transport means;
   wherein the transport means is configured for transporting the substrate over the first and second tanks such that a surface of the substrate to be treated is in direct contact with at least one of the electrolyte filled in the at least one first tank or the electrolyte filled in the at least one second tank, thereby conducting a charge transfer between the first electrode and the substrate and between the substrate and the second electrode and resulting in an electrochemical treatment of the substrate surface.

### EXAMPLE 5

Apparatus for electrochemical treating of a semiconductor substrate according to example 4, comprising two or more first tanks, wherein the first tanks are arranged in separate sectors of the treating area, and
wherein a second tank is arranged between neighboring ones of the first tanks and is separated from the first tanks by the separation unit.

### EXAMPLE 6

Apparatus for electrochemical treating of a semiconductor substrate according to example 4 or example 5, wherein the first tanks in the separate sectors of the treating area are circularly arranged with an n-folded rotationally symmetry in the treating area.

### EXAMPLE 7

Apparatus according to any of examples 4 to 6, wherein the first tank in a first sector has a smaller size in its surface area compared to the first tank in a second sector and, optionally, the size of the surface area of the first tank in the third and further sectors is bigger than the surface area of the first tank in the second sector.

### EXAMPLE 8

Apparatus according to example 7, wherein the first tanks in each of the sectors have a triangle or sector shape and their side walls have different extensions from the outer rim of the treating area of the apparatus, while the tips of the tanks are aligned such that they are positioned on a line formed in a spiral shape extending from the center of the bottom plane of the apparatus.

### EXAMPLE 9

Apparatus for electrochemical treating of a semiconductor substrate comprising:
a plurality of first tanks filled with an electrolyte, each comprising a first electrode,
a second tank filled with an electrolyte and comprising a second electrode,
a separation unit that electrically separates the plurality of first tanks from the second tank including their electrolytes,
an electric power supply connected to the first electrodes and the second electrode, and
a transport means;
   wherein the transport means is configured for transporting the substrate over the plurality of first tanks and the second tank such that a surface of the substrate to be treated is in direct contact with the electrolyte filled in the first tank or the electrolyte filled in the second tank, thereby conducting a charge transfer between the first electrode and the substrate and between the substrate and the second electrode and resulting in an electrochemical treatment of the substrate surface,
   wherein a plurality of the first tanks is arranged in the second tank.

### EXAMPLE 10

Apparatus for electrochemical treating of a semiconductor substrate according to example 8, wherein the first tanks have a circular shape.

### EXAMPLE 11

Apparatus for electrochemical treating of a semiconductor substrate according to example 8 or example 9, wherein the first tanks are arranged in a dot pattern within the second tank.

### EXAMPLE 12

Apparatus for electrochemical treating of a semiconductor substrate according to any of the preceding examples, wherein the first or second electrode is a surface electrode.

### EXAMPLE 13

Apparatus for electrochemical treating of a semiconductor substrate according to any of the preceding examples,
wherein the first tank is an anode tank, the first electrode is an anode, the second tank is a cathode tank, and the second electrode is a cathode, or
wherein the first tank is a cathode tank, the first electrode is a cathode, the second tank is an anode tank, and the second electrode is an anode.

### EXAMPLE 14

Apparatus for electrochemical treating of a semiconductor substrate according to any of the preceding examples, wherein, in a top view, the treating area of the first tank is similar to the treating area of the second tank.

### EXAMPLE 15

Apparatus for electrochemical treating of a semiconductor substrate according to any of the preceding examples, wherein the transport means is configured to rotate the substrate around its axis and move the substrate in a lateral direction over the first and second tanks.

### EXAMPLE 16

Apparatus for electrochemical treating of a semiconductor substrate according to example 15, wherein the motion in lateral direction is a translational movement of the substrate in a plane parallel to the planes of the first and second tanks.

### EXAMPLE 17

Apparatus for electrochemical treating a semiconductor substrate according to example 15 or example 16, wherein the motion in lateral direction comprises an eccentric movement of the substrate in a plane parallel to the planes of the first and second tanks.

### EXAMPLE 18

A process for electrochemical treating of semiconductor substrates using the apparatus according to any of the preceding examples, comprising the step of transporting the substrate over the first and second tanks, wherein the transport means is configured such that a surface of the substrate to be treated is in direct contact with at least one of the electrolytes filled in the first and second tanks, thereby conducting a charge transfer between the first electrode and the substrate and between the substrate and the second electrode and resulting in a electrochemical treatment of the substrate surface.

### EXAMPLE 19

The process according to example 18 for porosifying a semiconductor substrate.

### EXAMPLE 20

The process according to any of examples 18 to 19, wherein the power supply supplies pulses of direct power, alternately having a different polarity in each pulse.

1-18. (canceled)

19. An apparatus for electrochemical treating of a semiconductor substrate, the apparatus comprising:
at least one first tank filled with an electrolyte and comprising at least one first electrode;
at least one second tank filled with an electrolyte and comprising at least one second electrode;
a separation unit that electrically separates the at least one first tank from the at least one second tank, including the electrolytes;
an electric power supply connected to the at least one first electrode and the at least one second electrode;
an arm configured to transport the semiconductor substrate over the first and second tanks, such that a surface of the semiconductor substrate to be treated comes into direct contact with at least one of the electrolyte in the at least one first tank and the electrolyte in the at least one second tank and a charge transfer conducts between the at least one first electrode and the semiconductor substrate and between the semiconductor substrate and the at least one second electrode, wherein the charge transfer causes an electrochemical treatment of the surface of the semiconductor substrate; and
a controller configured to control the arm such that the semiconductor substrate masks, in a top view, the at least one first electrode and/or the at least one second electrode during the transport of the semiconductor substrate over the first and second tanks most of the time during the electrochemical treatment of the surface of the semiconductor substrate.

20. The apparatus of claim 19, further comprising a treating area comprising the at least one first tank and the at least one second tank, wherein in the top view, the treating area has a circular, oval or elliptic shape.

21. The apparatus of claim 20, wherein in the top view, the treating area has an oval or elliptical shape, and wherein the at least one first electrode and/or the at least one second electrode are located in a circular arrangement inside the treating area.

22. The apparatus of claim 20, further comprising a perforated plate configured to reduce the treating area in the top view.

23. The apparatus of claim 20, further comprising current baffles provided at least at parts of the treating area comprising the at least one first electrode and the at least one second electrode.

24. The apparatus of claim 23, wherein the current baffles are perforated sheets.

25. The apparatus of claim 20, wherein the at least one first tank comprises two or more first tanks, wherein the two or more first tanks are arranged in separate sectors of the treating area, and wherein a second tank is arranged between neighboring ones of the two or more first tanks and is separated from the neighboring ones of the first tanks by the separation unit.

26. The apparatus of claim 25, wherein the two or more first tanks are in separate sectors of the treating area and circularly arranged with an n-folded rotational symmetry in the treating area.

27. The apparatus of claim 19, wherein the at least one first electrode or the at least one second electrode is a surface electrode.

28. The apparatus of claim 19, wherein the controller is configured to switch off at least parts of the at least one first electrode and/or the at least one second electrode.

29. The apparatus of claim 19, wherein the at least one first tank is an anode tank, the at least one first electrode is an anode, the at least one second tank is a cathode tank, and the at least one second electrode is a cathode.

30. The apparatus of claim 19, wherein the at least one first tank is a cathode tank, the at least one first electrode is a cathode, the at least one second tank is an anode tank, and the at least one second electrode is an anode.

31. The apparatus of claim 19, wherein in the top view, a treating area of the at least one first tank is similar to a treating area of the at least one second tank.

32. The apparatus of claim 19, wherein the arm is configured to rotate the semiconductor substrate around an axis of the semiconductor substrate and move the semiconductor substrate in a lateral direction over the at least one first tank and the at least one second tank.

33. The apparatus of claim 32, wherein the motion in the lateral direction is a translational movement of the semiconductor substrate in a plane parallel to a plane of the at least one first tank and a plane of the at least one second tank.

34. The apparatus of claim 32, wherein the motion in the lateral direction comprises an eccentric movement of the semiconductor substrate in a plane parallel to a plane of the at least one first tank and a plane of the at least one second tank.

35. A method for electrochemical treating of semiconductor substrates using an apparatus that includes at least one first tank filled with an electrolyte and comprising at least one first electrode, at least one second tank filled with an electrolyte and comprising at least one second electrode, a separation unit that electrically separates the at least one first tank from the at least one second tank, including the electrolytes, an electric power supply connected to the at least one first electrode and the at least one second electrode, and an arm configured to transport the semiconductor substrate over the first and second tanks, the method comprising:
transporting the semiconductor substrate via the arm over the at least one first tank and the at least one second tank, wherein the transporting includes bringing a surface of a semiconductor substrate to be treated into direct contact with at least one of the electrolyte in the at least one first tank and the electrolyte in the at least one second tank, such that a charge transfer conducts between the at least one first electrode and the semiconductor substrate and between the semiconductor substrate and the at least one second electrode, the charge transfer causing an electrochemical treatment of the surface of the semiconductor substrate; and
controlling the arm such that the semiconductor substrate masks, in a top view, the at least one first electrode and/or the at least one second electrode during the transporting of the semiconductor substrate over the first and second tanks most of the time during the electrochemical treatment of the surface of the semiconductor substrate.

36. The method of claim 35, further comprising porosifying the semiconductor substrate.

37. The method of claim 35, wherein the power supply supplies pulses of direct power, alternately having a different polarity in each pulse.
